(19) United States
(12) Patent Application Publication
(10) Pub. No.: US 2025/0160184 A1
(43) Pub. Date: May 15, 2025

(54) DISPLAY DEVICE

(71) Applicant: LG Display Co., Ltd., Seoul (KR)

(72) Inventor: Howon CHOI, Paju-si (KR)

(73) Assignee: LG Display Co., Ltd., Seoul (KR)

(21) Appl. No.: 18/915,002

(22) Filed: Oct. 14, 2024

(30) Foreign Application Priority Data
Nov. 14, 2023 (KR) 10-2023-0157500

(51) Int. Cl. H10K 59/80; H10K 59/122

(52) U.S. Cl. CPC H10K 59/879; H10K 59/122; H10K 59/80515

(57) ABSTRACT

Embodiments of the present disclosure relate to a display device. By including a first electrode layer which is disposed on a passivation layer including at least one hole in an emitting area and is located in an area other than the at least one hole or by including a first electrode layer including an upper electrode layer and a lower electrode layer which is located under the upper electrode layer, it is possible to provide a display device capable of improving light extraction efficiency.

### CROSS-REFERENCE TO RELATED APPLICATIONS

This application claims the benefit of and priority to Korean Patent Application No. 10-2023-0157500 filed on Nov. 14, 2023, the entire contents of which are incorporated herein by reference for all purposes as if fully set forth herein.

### BACKGROUND

### 1. Technical Field

Embodiments of the present disclosure relate to a display device.

### 2. Description of the Related Art

An organic light emitting display device is a self-emissive display device, and unlike a liquid crystal display device, may be manufactured in a lightweight and thin form since a separate light source is not required.

The organic light emitting display device is not only advantageous in terms of power consumption due to low-power driving, but also has excellent color reproduction, response speed, viewing angle and contrast ratio. Thus, the organic light emitting display device is being studied as a next-generation display.

Light emitted from the light emitting layer of the organic light emitting display device passes through various components of the organic light emitting display device and comes out of the organic light emitting display device.

However, among light emitted from the light emitting layer, there is light that does not come out of the organic light emitting display device and is trapped inside the organic light emitting display device, causing a problem in the light extraction efficiency of the organic light emitting display device.

In order to improve the light extraction efficiency of such an organic light emitting display device, a method of forming a micro lens array (MLA) in the overcoat layer of the organic light emitting display device has been proposed.

However, despite forming the micro lens array (MLA) in the overcoat layer of the organic light emitting display device, there is a problem in that a lot of light is trapped inside the organic light emitting display device and thus the amount of light extracted to the outside is not large.

Therefore, there is a demand for an organic light emitting display device which can improve luminous efficiency and light extraction efficiency.

The description of the related art should not be assumed to be prior art merely because it is mentioned in or associated with this section. The description of the related art includes information that describes one or more aspects of the subject technology, and the description in this section does not limit the invention.

### SUMMARY

Embodiments of the present disclosure may provide a display device capable of improving light extraction efficiency.

Embodiments of the present disclosure may provide a display device capable of low-power driving by recycling light to be internally extinguished.

According to example embodiments of the present disclosure, a display device may include: a substrate including an emitting area and a non-emitting area; an overcoat layer disposed on the substrate; a passivation layer disposed on the overcoat layer, and including at least one hole in the emitting area; a first electrode layer disposed on an upper surface of the passivation layer, and located in an area other than the at least one hole; a light emitting layer disposed on the first electrode layer, and covering the overcoat layer and the passivation layer in the at least one hole; and a second electrode layer disposed on the light emitting layer.

According to example embodiments of the present disclosure, a display device may include: a substrate including an emitting area and a non-emitting area; an overcoat layer disposed on the substrate; a first electrode layer disposed on the overcoat layer, having at least one hole in the emitting area, and including an upper electrode layer and a lower electrode layer which is located under the upper electrode layer; a light emitting layer disposed on the first electrode layer, and covering the overcoat layer and the first electrode layer in the at least one hole; and a second electrode layer disposed on the light emitting layer.

According to example embodiments of the present disclosure, a display device may include: a substrate; an overcoat layer disposed on the substrate; a passivation layer disposed on the overcoat layer, and including at least one hole exposing a partial upper surface of the overcoat layer; a first electrode layer disposed on an upper surface of the passivation layer, and exposing the at least one hole; a light emitting layer disposed on the first electrode layer and in the at least one hole; and a second electrode layer disposed on the light emitting layer.

According to the example embodiments of the present disclosure, it is possible to provide a display device capable of improving light extraction efficiency.

According to the example embodiments of the present disclosure, it is possible to provide a display device capable of low-power driving by recycling light to be internally extinguished.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a diagram showing the schematic system configuration of a display device according to example embodiments of the present disclosure.

FIG. 2 is a cross-sectional view of an example of a pixel structure disposed in the display panel of a display device according to an example embodiment of the present disclosure.

FIG. 3 is a cross-sectional view of an example of a pixel structure disposed in the display panel of a display device according to another example embodiment of the present disclosure.

FIG. 4 is a cross-sectional view of an example of a pixel structure disposed in the display panel of a display device according to another example embodiment of the present disclosure.

FIG. 5 is a cross-sectional view of an example of a pixel structure disposed in the display panel of a display device according to another example embodiment of the present disclosure.

FIG. 6 is an enlarged view of the area A of FIG. 5.

FIG. 7 is a cross-sectional view of an example of a pixel structure disposed in the display panel of a display device according to another example embodiment of the present disclosure.

FIG. 8 is a cross-sectional view of an example of a pixel structure disposed in the display panel of a display device according to another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various example embodiments of the present disclosure will be described in detail with reference to accompanying drawings.

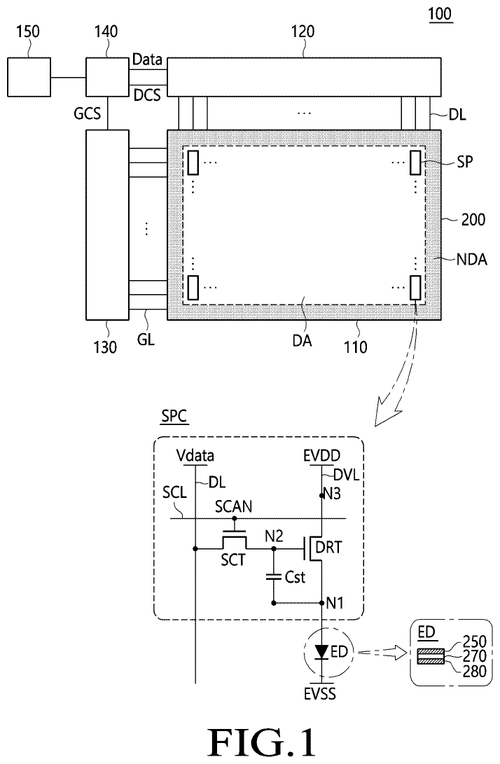

FIG. 1 is a diagram showing the schematic system configuration of a display device according to example embodiments of the present disclosure.

Referring to FIG. 1, the driving system of the display device 100 according to the example embodiments of the present disclosure may include a display panel 110 and a display driving circuit for driving the display panel 110.

The display panel 110 may include a display area DA in which an image is displayed and a non-display area NDA in which an image is not displayed.

The display panel 110 may include a plurality subpixels SP which are disposed on a substrate 200 to display an image.

The substrate 200 may include an emitting area and a non-emitting area.

The display panel 110 may include a plurality of signal wirings which are disposed on the substrate 200.

For example, the plurality of signal wirings may include data lines DL, gate lines GL, driving voltage lines, etc.

Each of the plurality of data lines DL may be disposed to extend in a first direction (a column direction in an example or a row direction in another example), and each of the plurality of gate lines GL may be disposed to extend in a second direction (a row direction in an example or a column direction in another example) orthogonal to the first direction.

The display driving circuit may include a data driving circuit 120, a gate driving circuit 130 and a controller 140.

The controller 140 may control the data driving circuit 120 and the gate driving circuit 130.

The data driving circuit 120 may output data signals corresponding to an image signal to the plurality of data lines DL.

The gate driving circuit 130 may generate gate signals and output the gate signals to the plurality of gate lines GL.

The controller 140 may convert input image data inputted from an external host 150 to suit a data signal format employed in the data driving circuit 120, and may supply the converted image data Data to the data driving circuit 120. The controller 140 may also supply a data control signal DCS to the data driving circuit 120, and supply a gate control signal GCS to the gate driving circuit 130.

The data driving circuit 120 may include at least one source driver integrated circuit.

For example, each source driver integrated circuit may be connected to the display panel 110 in a tape automated bonding (TAB) method, may be connected to the bonding pads of the display panel 110 in a chip-on-glass (COG) or chip-on-panel (COP) method, or may be connected to the display panel 110 by being implemented in a chip-on-film (COF) method.

The gate driving circuit 130 may be connected to the display panel 110 in a tape automated bonding (TAB) method, may be connected to the bonding pads of the display panel 110 in a COG or COP method, may be connected to the display panel 110 according to a COF method, or may be formed in the non-display area NDA of the display panel 110 in a gate-in-panel (GIP) type.

Referring to FIG. 1, in the display device 100 according to the example embodiments of the present disclosure, each subpixel SP may include a light emitting element ED and a pixel driving circuit SPC for driving the light emitting element ED.

The pixel driving circuit SPC may include a driving transistor DRT, a scan transistor SCT and a storage capacitor Cst.

The driving transistor DRT may drive the light emitting element ED by controlling current flowing to the light emitting element ED.

The scan transistor SCT may transfer a data voltage Vdata to a second node N2, which is the gate node of the driving transistor DRT.

The storage capacitor Cst may be configured to maintain a voltage for a predetermined period of time.

The light emitting element ED may include a first electrode layer 250, a second electrode layer 280 and a light emitting layer 270.

The light emitting layer 270 is located between the first electrode layer 250 and the second electrode layer 280.

The first electrode layer 250 may be a pixel electrode which is involved in the formation of the light emitting element ED of each subpixel SP, and may be electrically connected to a first node N1 of the driving transistor DRT.

The second electrode layer 280 may be a common electrode which is involved in the formation of the light emitting elements ED of all subpixels SP, and may be applied with a base voltage EVSS.

For example, the light emitting element ED may be an organic light emitting diode (OLED), an inorganic-based light emitting diode (LED) or a quantum dot (QD) light emitting element.

When the display device 100 according to the example embodiments of the present disclosure is an OLED display, each subpixel SP may include, as a light emitting element, an organic light emitting diode (OLED).

When the display device 100 according to the example embodiments of the present disclosure is a quantum dot (QD) light emitting element, each subpixel SP may include a light emitting element made of quantum dots (QD).

When the display device 100 according to the example embodiments of the present disclosure is a micro LED display, each subpixel SP may include, as a light emitting element, a micro light emitting diode (micro LED) which emits light on its own and is made on the basis of an inorganic material.

The driving transistor DRT as a transistor for driving the light emitting element ED may include the first node N1, the second node N2 and a third node N3.

The first node N1 may be a source or drain node, and may be electrically connected to the first electrode layer 250 of the light emitting element ED.

The second node N2 may be the gate node, and may be electrically connected to a source or drain node of the scan transistor SCT.

The third node N3 may be a drain or source node, and may be electrically connected to a driving voltage line DVL which supplies a driving voltage EVDD.

In the present specification, it will be described as an example that the first node N1 is a source node and the third node N3 is a drain node.

The scan transistor SCT may switch the connection between a data line DL and the second node N2 of the driving transistor DRT.

In response to a scan signal SCAN supplied from a scan line SCL as a type of gate line GL, the scan transistor SCT may control the connection between the second node N2 of the driving transistor DRT and a corresponding data line DL among the plurality of data lines DL.

The storage capacitor Cst may be configured between the first node N1 and the second node N2 of the driving transistor DRT.

The structure of the subpixel SP shown in FIG. 1 is nothing but a mere example for explanation, and may further include at least one transistor or at least one capacitor.

Each of the plurality of subpixels SP may have the same structure, and some of the plurality of subpixels SP may have a different structure.

Each of the driving transistor DRT and the scan transistor SCT may be an n-type transistor or a p-type transistor.

The display device 100 according to the example embodiments of the present disclosure may have a top emission structure or a bottom emission structure.

Hereinafter, in the present specification, the bottom emission structure will be described as an example.

For example, in the case of the bottom emission structure, the first electrode layer 250 may be a conductive material which transmits or semi-transmits light, and the second electrode layer 280 may be reflective metal.

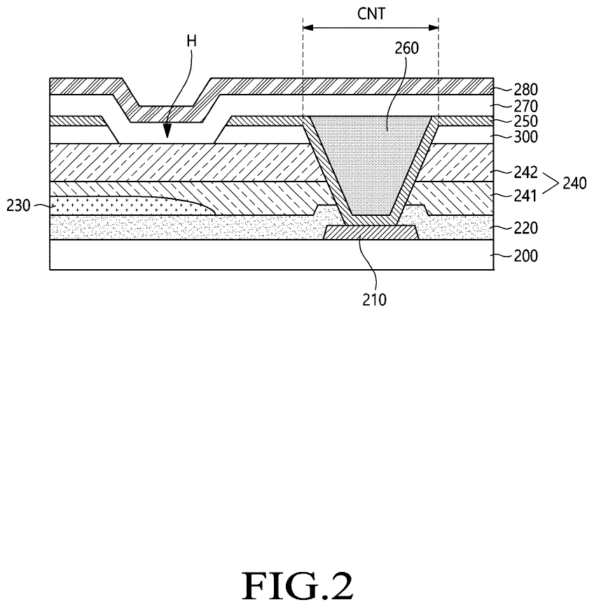

FIG. 2 is a cross-sectional view of an example of a pixel structure disposed in the display panel of a display device according to an example embodiment of the present disclosure.

Referring to FIG. 2, a connection pattern 210 which is electrically connected to a transistor may be disposed on a substrate 200.

For example, the connection pattern 210 may electrically connect the driving transistor DRT and the light emitting element ED, but is not limited thereto.

A buffer layer 220 which covers the connection pattern 210 may be disposed on the substrate 200.

A color filter layer 230 may be disposed on the buffer layer 220.

In addition, an overcoat layer 240 which covers the color filter layer 230 may be disposed on the buffer layer 220.

The overcoat layer 240 may be a single layer or a multilayer, but in FIG. 2, the display device in which the overcoat layer 240 is composed of two layers will be described as an example.

When the overcoat layer 240 is composed of two layers, the overcoat layer 240 may include a first overcoat layer 241 which is disposed on the buffer layer 220 and covers the color filter layer 230 and a second overcoat layer 242 which is disposed on the first overcoat layer 241.

The first overcoat layer 241 and the second overcoat layer 242 may be made of different materials to improve light extraction efficiency.

For example, the first overcoat layer 241 and the second overcoat layer 242 may be designed to have different refractive indexes to improve light extraction efficiency.

However, the example embodiment of the present disclosure is not limited thereto, and the first overcoat layer 241 and the second overcoat layer 242 may be made of substantially the same material.

Being substantially the same in the present disclosure may mean the same degree in consideration of a minute difference due to an error in a process.

Referring to FIG. 2, the display device according to the first example embodiment of the present disclosure may include a passivation layer 300 which is disposed on the overcoat layer 240 and includes at least one hole H in an emitting area, a first electrode layer 250 which is disposed on the upper surface of the passivation layer 300 and is located in an area other than the at least one hole H, a light emitting layer 270 which is disposed on the first electrode layer 250 and covers the overcoat layer 240 and the passivation layer 300 in the hole H, and a second electrode layer 280 which is disposed on the light emitting layer 270.

The first electrode layer 250 may include a conductive material which transmits or semi-transmits light.

For example, the first electrode layer 250 may include at least one type of transparent conductive oxide such as indium tin oxide (ITO), indium zinc oxide (IZO), indium tin zinc oxide (ITZO), zinc oxide and tin oxide, or may include translucent metal such as magnesium, silver and alloy of magnesium and silver.

The light emitting layer 270 of the light emitting element ED may be formed by a deposition or coating method that has directionality.

For example, the light emitting layer 270 may be formed by physical vapor deposition (PVD).

The light emitting layer 270 may include a red organic light emitting layer disposed in a red subpixel (R), a green organic light emitting layer disposed in a green subpixel (G), and a blue organic light emitting layer disposed in a blue subpixel (B).

The second electrode layer 280 may include reflective metal.

FIG. 2 illustrates a configuration in which the second electrode layer 280 is a single layer. However, the example embodiment of the present disclosure is not limited thereto, and the second electrode layer 280 may be composed of a multilayer.

For example, when the second electrode layer 280 is composed of a multilayer, at least one layer may include reflective metal.

For example, the second electrode layer 280 may include at least one of aluminum, neodymium, nickel, titanium, tantalum, copper, silver and aluminum alloy, but the example embodiment of the present disclosure is not limited thereto.

In the display device according to the first example embodiment of the present disclosure, as the first electrode layer 250 is located on the upper surface of the passivation layer 300 and is located in the area other than the at least one hole H, it is possible to prevent the thickness of the second electrode layer 280 from being reduced.

The passivation layer 300 may use an oxide- or nitride-based material, but is not limited thereto.

When the thickness of the passivation layer 300 is larger than the thickness of the first electrode layer 250, it is possible to prevent the thickness of the second electrode layer 280 from being reduced and improve light extraction efficiency.

The thickness of the passivation layer 300 may be 100 nm to 1000 nm.

In this way, by adjusting the thickness of the passivation layer 300, the depth of the hole H may be adjusted.

The first example embodiment of the present disclosure may further include a contact part CNT which passes through the passivation layer 300 and the overcoat layer 240.

In the contact part CNT, the first electrode layer 250 and the connection pattern 210 which is disposed on the substrate 200 may be electrically connected.

A bank layer 260 which is disposed on the first electrode layer 250 and fills the contact part CNT may be further included.

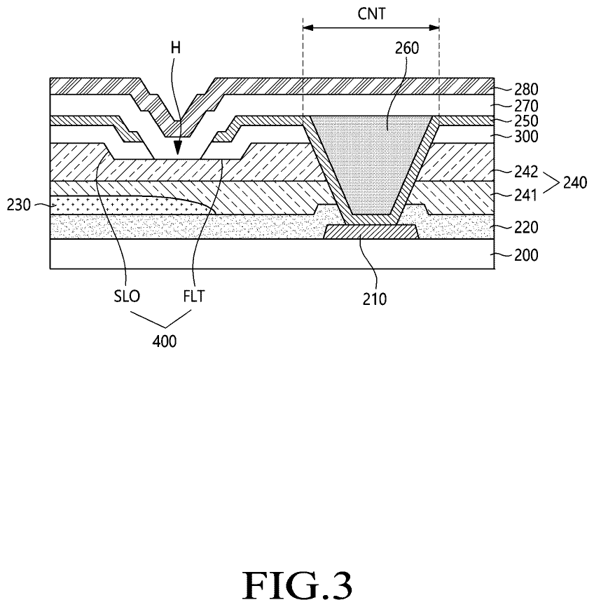

FIG. 3 is a cross-sectional view of an example of a pixel structure disposed in the display panel of a display device according to another example embodiment of the present disclosure.

Details regarding the substrate 200, the connection pattern 210, the buffer layer 220, the color filter layer 230, the overcoat layer 240, the first electrode layer 250, the bank layer 260, the light emitting layer 270, the second electrode layer 280, the passivation layer 300, the hole H and the contact part CNT of FIG. 3 may be substantially the same as details regarding the substrate 200, the connection pattern 210, the buffer layer 220, the color filter layer 230, the overcoat layer 240, the first electrode layer 250, the bank layer 260, the light emitting layer 270, the second electrode layer 280, the passivation layer 300, the hole H and the contact part CNT described above with reference to FIG. 2.

Referring to FIG. 3, the overcoat layer 240 of the display device according to the second example embodiment of the present disclosure may include at least one concave part 400 which is composed of a flat portion FLT and a sloped portion SLO surrounding the flat portion FLT.

The passivation layer 300 may cover the sloped portion SLO and overlap at least a partial area of the flat portion FLT.

An area where the passivation layer 300 does not overlap the flat portion FLT may overlap the light emitting layer 270.

As the overcoat layer 240 includes the concave part 400, when forming the passivation layer 300 and the light emitting layer 270, the passivation layer 300 and the light emitting layer 270 may be formed according to the shape of the concave part 400.

As the overcoat layer 240 includes the concave part 400 and the passivation layer 300 includes the hole H, when forming the second electrode layer 280, the second electrode layer 280 may be formed according to the shapes of the concave part 400 and the hole H. Therefore, it is possible to prevent the thickness of the second electrode layer 280 from being reduced and improve light extraction efficiency.

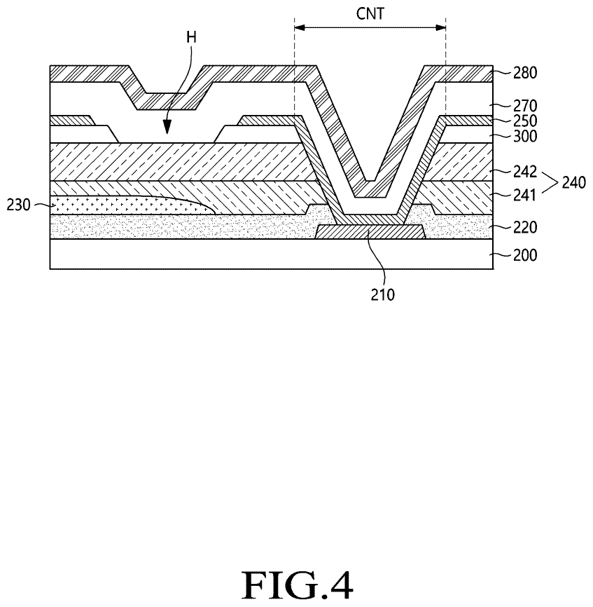

FIG. 4 is a cross-sectional view of an example of a pixel structure disposed in the display panel of a display device according to another example embodiment of the present disclosure.

Details regarding the substrate 200, the connection pattern 210, the buffer layer 220, the color filter layer 230, the overcoat layer 240, the first electrode layer 250, the light emitting layer 270, the second electrode layer 280, the passivation layer 300, the hole H and the contact part CNT of FIG. 4 may be substantially the same as details regarding the substrate 200, the connection pattern 210, the buffer layer 220, the color filter layer 230, the overcoat layer 240, the first electrode layer 250, the light emitting layer 270, the second electrode layer 280, the passivation layer 300, the hole H and the contact part CNT described above with reference to FIG. 2.

Referring to FIG. 4, in the display device according to the third example embodiment of the present disclosure, the light emitting layer 270 and the second electrode layer 280 may be disposed in the contact part CNT according to the shape of the contact part CNT.

Accordingly, it is possible to perform the function of the light emitting element ED even in the contact part CNT.

As the second electrode layer 280 is formed according to the shape of the contact part CNT, light to be internally extinguished may be recycled and may be extracted to the outside.

In other words, the second electrode layer 280 may perform the function of a micro lens array (MLA).

However, the example embodiment of the present disclosure is not limited thereto, and a micro lens array (MLA) may be formed on the overcoat layer 240 to improve light extraction efficiency.

The micro lens array (MLA) which is formed on the overcoat layer 240 may include reflective metal like the second electrode layer 280.

In order to increase the area of the second electrode layer 280 and thereby improve light extraction efficiency, it is preferable to form the overcoat layer 240 to be composed of at least two layers.

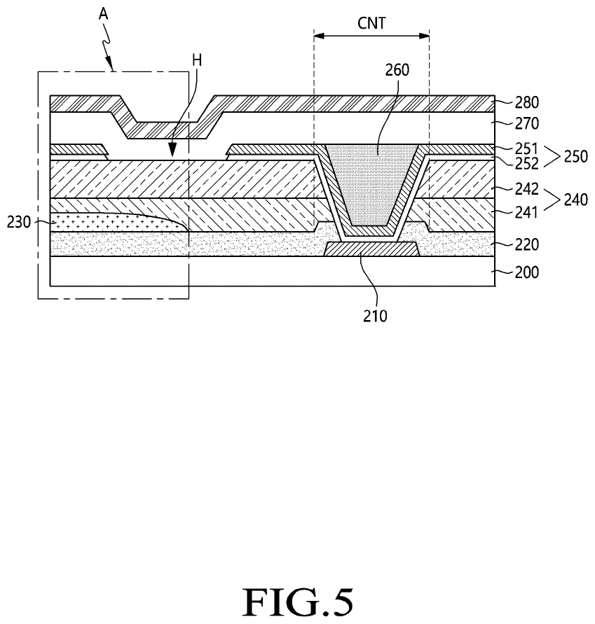

FIG. 5 is a cross-sectional view of an example of a pixel structure disposed in the display panel of a display device according to another example embodiment of the present disclosure.

Referring to FIG. 5, a connection pattern 210 which is electrically connected to a transistor may be disposed on a substrate 200.

For example, the connection pattern 210 may electrically connect the driving transistor DRT and the light emitting element ED, but is not limited thereto.

A buffer layer 220 which covers the connection pattern 210 may be disposed on the substrate 200.

A color filter layer 230 may be disposed on the buffer layer 220.

In addition, an overcoat layer 240 which covers the color filter layer 230 may be disposed on the buffer layer 220.

The overcoat layer 240 may be a single layer or a multilayer, but in FIG. 5, the display device in which the overcoat layer 240 is composed of two layers will be described as an example.

When the overcoat layer 240 is composed of two layers, the overcoat layer 240 may include a first overcoat layer 241 which is disposed on the buffer layer 220 and covers the color filter layer 230 and a second overcoat layer 242 which is disposed on the first overcoat layer 241.

The first overcoat layer 241 and the second overcoat layer 242 may be made of different materials to improve light extraction efficiency.

For example, the first overcoat layer 241 and the second overcoat layer 242 may be designed to have different refractive indexes to improve light extraction efficiency.

However, the example embodiment of the present disclosure is not limited thereto, and the first overcoat layer 241 and the second overcoat layer 242 may be made of substantially the same material.

Referring to FIG. 5, the display device according to the fourth example embodiment of the present disclosure may include a first electrode layer 250 which is disposed on the overcoat layer 240 and includes at least one hole H in an emitting area, a light emitting layer 270 which is disposed on the first electrode layer 250 and covers the overcoat layer 240 and the first electrode layer 250 in the hole H, and a second electrode layer 280 which is disposed on the light emitting layer 270.

The first electrode layer 250 may include a conductive material which transmits or semi-transmits light.

For example, the first electrode layer 250 may include at least one type of transparent conductive oxide such as indium tin oxide (ITO), indium zinc oxide (IZO), indium tin zinc oxide (ITZO), zinc oxide and tin oxide, or may include translucent metal such as magnesium, silver and alloy of magnesium and silver.

The first electrode layer 250 may include an upper electrode layer 251 and a lower electrode layer 252 which is located under the upper electrode layer 251.

The thickness of the lower electrode layer 252 may be smaller than the thickness of the upper electrode layer 251.

If the thickness of the lower electrode layer 252 is smaller than the thickness of the upper electrode layer 251, when the second electrode layer 280 is formed according to the shape of the hole H, it is possible to prevent the thickness of the second electrode layer 280 from being reduced.

The lower electrode layer 252 may be formed using a material whose etch rate is greater than the etch rate of the upper electrode layer 251.

For example, the upper electrode layer 251 may be made of ITO, and the lower electrode layer 252 may be made of at least one selected among transparent conductive oxide or translucent metal with a higher etch rate than ITO.

The lower electrode layer 252 may preferably be made of IZO.

As the lower electrode layer 252 is formed using a material whose etch rate is greater than the etch rate of the upper electrode layer 251, in an etching step, the lower electrode layer 252 may be etched more than the upper electrode layer 251 to form an undercut UC.

By forming the undercut UC, when forming the second electrode layer 280, it is possible to prevent the thickness of the second electrode layer 280 from being reduced.

The light emitting layer 270 of the light emitting element ED may be formed by a deposition or coating method that has directionality.

For example, the light emitting layer 270 may be formed by physical vapor deposition (PVD).

The light emitting layer 270 may include a red organic light emitting layer disposed in a red subpixel (R), a green organic light emitting layer disposed in a green subpixel (G), and a blue organic light emitting layer disposed in a blue subpixel (B).

The second electrode layer 280 may include reflective metal.

FIG. 5 illustrates a configuration in which the second electrode layer 280 is a single layer. However, the example embodiment of the present disclosure is not limited thereto, and the second electrode layer 280 may be composed of a multilayer.

For example, when the second electrode layer 280 is composed of a multilayer, at least one layer may include reflective metal.

For example, the second electrode layer 280 may include at least one of aluminum, neodymium, nickel, titanium, tantalum, copper, silver and aluminum alloy, but the example embodiment of the present disclosure is not limited thereto.

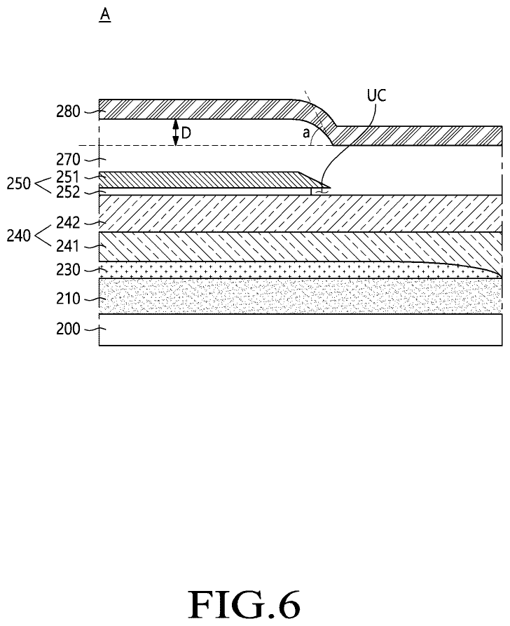

FIG. 6 is an enlarged view of the area A of FIG. 5.

Referring to FIG. 6, as described above, the lower electrode layer 252 may be disposed under the upper electrode layer 251.

In addition, as described above, as the lower electrode layer 252 is formed using a material whose etch rate is greater than the etch rate of the upper electrode layer 251, in an etching step, the lower electrode layer 252 may be etched more than the upper electrode layer 251 to form the undercut UC.

Referring to FIG. 6, when the second electrode layer 280 is formed according to the shape of the hole H, a depression is formed by a taper angle a around the hole H and a step D is formed.

The height of the undercut UC may be adjusted by adjusting the thickness of the lower electrode layer 252, and the taper angle a and the height of the step D may be adjusted by adjusting the height of the undercut UC.

The preferred thickness of the lower electrode layer 252 is 100 nm to 500 nm.

The fourth example embodiment of the present disclosure may further include a contact part CNT which passes through the overcoat layer 240.

In the contact part CNT, the first electrode layer 250 and the connection pattern 210 which is disposed on the substrate 200 may be electrically connected.

A bank layer 260 which is disposed on the first electrode layer 250 and fills the contact part CNT may be further included.

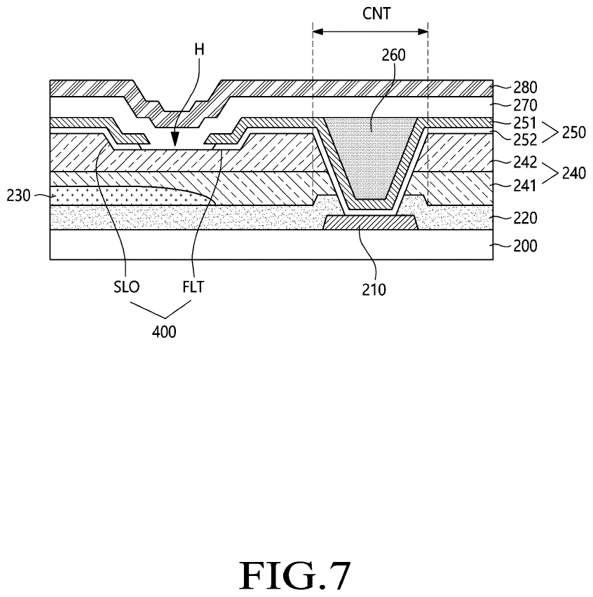

FIG. 7 is a cross-sectional view of an example of a pixel structure disposed in the display panel of a display device according to another example embodiment of the present disclosure.

Details regarding the substrate 200, the connection pattern 210, the buffer layer 220, the color filter layer 230, the overcoat layer 240, the first electrode layer 250, the upper electrode layer 251, the lower electrode layer 252, the bank layer 260, the light emitting layer 270, the second electrode layer 280, the hole H and the contact part CNT of FIG. 7 may be substantially the same as details regarding the substrate 200, the connection pattern 210, the buffer layer 220, the color filter layer 230, the overcoat layer 240, the first electrode layer 250, the upper electrode layer 251, the lower electrode layer 252, the bank layer 260, the light emitting layer 270, the second electrode layer 280, the hole H and the contact part CNT described above with reference to FIG. 5.

Referring to FIG. 7, the overcoat layer 240 of the display device according to the fifth example embodiment of the present disclosure may include at least one concave part 400 which is composed of a flat portion FLT and a sloped portion SLO surrounding the flat portion FLT.

The lower electrode layer 252 may cover the sloped portion SLO and overlap at least a partial area of the flat portion FLT.

An area where the lower electrode layer 252 does not overlap the flat portion FLT may overlap the light emitting layer 270.

As the overcoat layer 240 includes the concave part 400, when forming the light emitting layer 270, the light emitting layer 270 may be formed according to the shape of the concave part 400.

As the overcoat layer 240 includes the concave part 400 and the first electrode layer 250 includes the hole H, when forming the second electrode layer 280, the second electrode layer 280 may be formed according to the shapes of the concave part 400 and the hole H. Therefore, it is possible to prevent the thickness of the second electrode layer 280 from being reduced and improve light extraction efficiency.

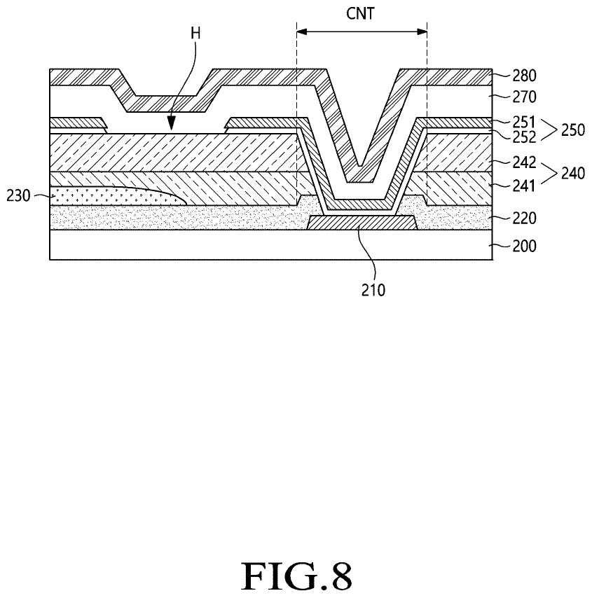

FIG. 8 is a cross-sectional view of an example of a pixel structure disposed in the display panel of a display device according to another example embodiment of the present disclosure.

Details regarding the substrate 200, the connection pattern 210, the buffer layer 220, the color filter layer 230, the overcoat layer 240, the first electrode layer 250, the upper electrode layer 251, the lower electrode layer 252, the light emitting layer 270, the second electrode layer 280, the hole H and the contact part CNT of FIG. 8 may be substantially the same as details regarding the substrate 200, the connection pattern 210, the buffer layer 220, the color filter layer 230, the overcoat layer 240, the first electrode layer 250, the upper electrode layer 251, the lower electrode layer 252, the light emitting layer 270, the second electrode layer 280, the hole H and the contact part CNT described above with reference to FIG. 5.

Referring to FIG. 8, in the display device according to the sixth example embodiment of the present disclosure, the light emitting layer 270 and the second electrode layer 280 may be disposed in the contact part CNT according to the shape of the contact part CNT.

Accordingly, it is possible to perform the function of the light emitting element ED even in the contact part CNT.

As the second electrode layer 280 is formed according to the shape of the contact part CNT, light to be internally extinguished may be recycled and may be extracted to the outside.

In order to increase the area of the second electrode layer 280 and thereby improve light extraction efficiency, it is preferable to form the overcoat layer 240 to be composed of at least two layers.

Various examples and aspects of the present disclosure are described below. These are provided as examples, and do not limit the scope of the present disclosure.

A display device according to example embodiments of the present disclosure may include a substrate including an emitting area and a non-emitting area; an overcoat layer disposed on the substrate; a passivation layer disposed on the overcoat layer, and including at least one hole in the emitting area; a first electrode layer disposed on an upper surface of the passivation layer, and located in an area other than the at least one hole; a light emitting layer disposed on the first electrode layer, and covering the overcoat layer and the passivation layer in the at least one hole; and a second electrode layer disposed on the light emitting layer.

In the display device according to the example embodiments of the present disclosure, a thickness of the passivation layer may be greater than a thickness of the first electrode layer.

In the display device according to the example embodiments of the present disclosure, the display device may further include a contact part passing through the passivation layer and the overcoat layer; and a bank layer disposed on the first electrode layer and filling the contact part. A connection pattern may be disposed on the substrate. The first electrode layer and the connection pattern may be electrically connected in the contact part.

In the display device according to the example embodiments of the present disclosure, the display device may further include a contact part passing through the passivation layer and the overcoat layer. A connection pattern may be disposed on the substrate. The first electrode layer and the connection pattern may be electrically connected in the contact part. The light emitting layer and the second electrode layer may be disposed according to a shape of the first electrode layer in the contact part.

In the display device according to the example embodiments of the present disclosure, the overcoat layer may be configured by at least two layers.

In the display device according to the example embodiments of the present disclosure, the overcoat layer may include at least one concave part which is configured by a flat portion and a sloped portion surrounding the flat portion, and the passivation layer may cover the sloped portion and overlap at least a partial area of the flat portion.

In the display device according to the example embodiments of the present disclosure, the display device may further include a contact part passing through the passivation layer and the overcoat layer; and a bank layer disposed on the first electrode layer and filling the contact part. A connection pattern may be disposed on the substrate. The first electrode layer and the connection pattern may be electrically connected in the contact part.

A display device according to example embodiments of the present disclosure may include a substrate including an emitting area and a non-emitting area; an overcoat layer disposed on the substrate; a first electrode layer disposed on the overcoat layer, having at least one hole in the emitting area, and including an upper electrode layer and a lower electrode layer which is located under the upper electrode layer; a light emitting layer disposed on the first electrode layer, and covering the overcoat layer and the first electrode layer in the at least one hole; and a second electrode layer disposed on the light emitting layer.

In the display device according to the example embodiments of the present disclosure, a thickness of the lower electrode layer may be less than a thickness of the upper electrode layer.

In the display device according to the example embodiments of the present disclosure, an etch rate of the lower electrode layer may be higher than an etch rate of the upper electrode layer.

In the display device according to the example embodiments of the present disclosure, the upper electrode layer may comprise indium tin oxide (ITO), and the lower electrode layer may comprise at least one selected among transparent conductive oxide or translucent metal with a higher etch rate than the ITO.

In the display device according to the example embodiments of the present disclosure, the display device may further include a contact part passing through the overcoat layer; and a bank layer disposed on the first electrode layer and filling the contact part. A connection pattern may be disposed on the substrate. The first electrode layer and the connection pattern may be electrically connected in the contact part.

In the display device according to the example embodiments of the present disclosure, the display device may further include a contact part passing through the overcoat layer. A connection pattern may be disposed on the substrate. The first electrode layer and the connection pattern may be electrically connected in the contact part. The light emitting layer and the second electrode layer may be disposed according to a shape of the first electrode layer in the contact part.

In the display device according to the example embodiments of the present disclosure, the overcoat layer may be configured by at least two layers.

In the display device according to the example embodiments of the present disclosure, the overcoat layer may include at least one concave part which is configured by a flat portion and a sloped portion surrounding the flat portion, and the lower electrode layer may cover the sloped portion and overlap at least a partial area of the flat portion.

In the display device according to the example embodiments of the present disclosure, the display device may further include a contact part passing through the overcoat layer; and a bank layer disposed on the first electrode layer and filling the contact part. A connection pattern may be disposed on the substrate. The first electrode layer and the connection pattern may be electrically connected in the contact part.

A display device according to example embodiments of the present disclosure may include a substrate; an overcoat layer disposed on the substrate; a passivation layer disposed on the overcoat layer, and including at least one hole exposing a partial upper surface of the overcoat layer; a first electrode layer disposed on an upper surface of the passivation layer, and exposing the at least one hole; a light emitting layer disposed on the first electrode layer and in the at least one hole; and a second electrode layer disposed on the light emitting layer.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device, comprising:
a substrate including an emitting area and a non-emitting area;
an overcoat layer disposed on the substrate;
a passivation layer disposed on the overcoat layer, and including at least one hole in the emitting area;
a first electrode layer disposed on an upper surface of the passivation layer, and located in an area other than the at least one hole;
a light emitting layer disposed on the first electrode layer, and covering the overcoat layer and the passivation layer in the at least one hole; and
a second electrode layer disposed on the light emitting layer.

2. The display device of claim 1, wherein a thickness of the passivation layer is greater than a thickness of the first electrode layer.

3. The display device of claim 1, further comprising:
a contact part passing through the passivation layer and the overcoat layer; and
a bank layer disposed on the first electrode layer and filling the contact part,
wherein:
a connection pattern is disposed on the substrate; and
the first electrode layer and the connection pattern are for being electrically connected in the contact part.

4. The display device of claim 1, further comprising:
a contact part passing through the passivation layer and the overcoat layer,
wherein a connection pattern is disposed on the substrate,
wherein the first electrode layer and the connection pattern are for being electrically connected in the contact part, and
wherein the light emitting layer and the second electrode layer are disposed according to a shape of the first electrode layer in the contact part.

5. The display device of claim 4, wherein the overcoat layer is configured by at least two layers.

6. The display device of claim 1, wherein
the overcoat layer includes at least one concave part which is configured by a flat portion and a sloped portion surrounding the flat portion, and
the passivation layer covers the sloped portion, and overlaps at least a partial area of the flat portion.

7. The display device of claim 6, further comprising:
a contact part passing through the passivation layer and the overcoat layer; and
a bank layer disposed on the first electrode layer and filling the contact part,
wherein:
a connection pattern is disposed on the substrate; and
the first electrode layer and the connection pattern are for being electrically connected in the contact part.

8. A display device, comprising:
a substrate including an emitting area and a non-emitting area;
an overcoat layer disposed on the substrate;
a first electrode layer disposed on the overcoat layer, having at least one hole in the emitting area, and including an upper electrode layer and a lower electrode layer which is located under the upper electrode layer;
a light emitting layer disposed on the first electrode layer, and covering the overcoat layer and the first electrode layer in the at least one hole; and
a second electrode layer disposed on the light emitting layer.

9. The display device of claim 8, wherein a thickness of the lower electrode layer is less than a thickness of the upper electrode layer.

10. The display device of claim 8, wherein an etch rate of the lower electrode layer is higher than an etch rate of the upper electrode layer.

11. The display device of claim 10, wherein the upper electrode layer comprises indium tin oxide (ITO), and the lower electrode layer comprises at least one selected among transparent conductive oxide or translucent metal with a higher etch rate than the ITO.

12. The display device of claim 10, further comprising:
a contact part passing through the overcoat layer; and
a bank layer disposed on the first electrode layer and filling the contact part,
wherein:
a connection pattern is disposed on the substrate; and
the first electrode layer and the connection pattern are for being electrically connected in the contact part.

13. The display device of claim 10, further comprising:
a contact part passing through the overcoat layer,
wherein a connection pattern is disposed on the substrate,
wherein the first electrode layer and the connection pattern are for being electrically connected in the contact part, and
wherein the light emitting layer and the second electrode layer are disposed according to a shape of the first electrode layer in the contact part.

14. The display device of claim 13, wherein the overcoat layer is configured by at least two layers.

15. The display device of claim 10, wherein
the overcoat layer includes at least one concave part which is configured by a flat portion and a sloped portion surrounding the flat portion, and
the lower electrode layer covers the sloped portion, and overlaps at least a partial area of the flat portion.

16. The display device of claim 15, further comprising:
a contact part passing through the overcoat layer; and
a bank layer disposed on the first electrode layer and filling the contact part,
wherein:
a connection pattern is disposed on the substrate; and
the first electrode layer and the connection pattern are for being electrically connected in the contact part.

17. A display device, comprising:
a substrate;
an overcoat layer disposed on the substrate;
a passivation layer disposed on the overcoat layer, and including at least one hole exposing a partial upper surface of the overcoat layer;
a first electrode layer disposed on an upper surface of the passivation layer, and exposing the at least one hole;
a light emitting layer disposed on the first electrode layer and in the at least one hole; and
a second electrode layer disposed on the light emitting layer.
